(19) United States
(12) Patent Application Publication
(10) Pub. No.: US 2026/0176793 A1
(43) Pub. Date: Jun. 25, 2026

(54) METHOD AND SYSTEM FOR ENHANCING GROWTH OF CHALCOGEN FILMS

(71) Applicant: NEXSTROM PTE. LTD., Singapore (SG)

(72) Inventors: Jing-Kai Huang, Singapore (SG); Chenyang Li, Singapore (SG)

(21) Appl. No.: 19/425,459

(22) Filed: Dec. 18, 2025

Related U.S. Application Data
(60) Provisional application No. 63/737,477, filed on Dec. 20, 2024.

(51) Int. Cl. C30B 29/46; C09K 11/68; C30B 25/18; H10D 62/80

(52) U.S. Cl. CPC C30B 29/46; C09K 11/681; C30B 25/183; H10D 62/883

(57) ABSTRACT

A device is described. The device includes a substrate and a transition metal chalcogen film formed on the substrate by vapor deposition. The transition metal chalcogen film is continuous over an area of the substrate and is at least one monolayer thick. The area has a dimension of at least two inches. The vapor deposition may use a metal precursor, a chalcogen precursor, and at least one additive.

### CROSS REFERENCE TO OTHER APPLICATIONS

This application claims priority to U.S. Provisional Patent Application No. 63/737,477 entitled METHOD AND SYSTEM FOR ENHANCING GROWTH OF CHALCOGEN FILMS filed Dec. 20, 2024 which is incorporated herein by reference for all purposes.

### BACKGROUND OF THE INVENTION

Transition metal chalcogenides (TMCs), such as transition metal dichalcogenides (TMDs), have garnered significant attention in the development of next-generation semiconductor technologies due to their remarkable electrical, optical, and mechanical properties. These materials exhibit unique characteristics such as high carrier mobility, tunable bandgaps, and excellent scalability, making them ideal candidates for a variety of applications, including logit devices, memory devices, electro-optical devices, and flexible electronics. For example, two-dimensional (2D) TMDs, such as MoS₂, WSe₂, WS₂, MoTe₂, MoSe₂, SnSe, and SnS, may be semiconductors. Such films, as well as other TMD materials (e.g., TMDs in the form of metals such as WTe₂, TiSe2), may be used in applications including but not limited to logic devices, memory devices, electro-optic devices (e.g. silicon photonics), and/or flexible devices (e.g., wearables and/or foldable devices). As the semiconductor industry continues to push toward smaller, faster, and more efficient devices, TMDs have emerged as a promising solution for sub-1 nm transistors, where traditional silicon-based materials encounter significant limitations.

To fabricate high-quality TMD films on a 12-inch wafer scale, metal-organic chemical vapor deposition (MOCVD) is currently regarded as the most viable and effective method. MOCVD allows for precise control over the composition, thickness, and uniformity of the deposited films, which is essential for ensuring the performance of TMDs in advanced electronic applications. However, achieving large-area, single-crystalline TMDs with minimal defects remains a significant challenge even for MOCVD. For example, the TMC films that are grown in a typical manner may have a reduced grain size, larger variations in thickness, a larger number of defects and/or significant contamination. Consequently, techniques for formation of chalcogenides, particularly 2D TMDs, are desired.

### BRIEF DESCRIPTION OF THE DRAWINGS

Various embodiments of the invention are disclosed in the following detailed description and the accompanying drawings.

FIGS. 1A-1B depict embodiments of systems for forming transition metal chalcogenide (e.g. transition metal dichalcogenide) films using advanced sources.

FIG. 2 is a flow chart depicting an embodiment of a method for forming transition metal chalcogenide (e.g. transition metal dichalcogenide) films using advanced sources for vapor deposition.

FIG. 3 is a flow chart depicting an embodiment of a method for forming transition metal chalcogenide (e.g. transition metal dichalcogenide) films using advanced sources for vapor deposition.

FIGS. 4A-4D depict embodiments of transition metal chalcogenide (e.g. transition metal dichalcogenide) films formed using advanced sources for vapor deposition.

FIG. 5 depicts an embodiment of the photoluminescence for a transition metal chalcogenide (e.g. transition metal dichalcogenide) film using advanced sources for vapor deposition.

FIGS. 6A-6B depict embodiments of Raman spectra for transition metal chalcogenide (e.g. transition metal dichalcogenide) films formed with and without using advanced sources for vapor deposition.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Transition metal chalcogenides (TMCs), especially transition metal dichalcogenides (TMDs), are increasingly important in next-generation semiconductor technologies due to their high carrier mobility, tunable bandgaps, and scalability. These properties make TMDs suitable for logic, memory, electro-optical, and flexible devices. For example, TMDs such as MoS₂, WSe₂, WS₂, MoTe₂, MoSe₂, SnSe, and SnS may serve as semiconductors, while metallic TMDs such as WTe₂ and TiSe₂ also have application in electronic devices. Such films may be fabricated using metal-organic chemical vapor depositions (MOCVD). Although TMDs are of interest, challenges remain in achieving large-area, single-crystalline TMDs with minimal defects, as conventional growth can result in reduced grain size, thickness variation, and contamination.

It has been determined that one obstacle in fabricating large scale, high quality TMD films is the selection of appropriate chalcogen sources. Pure chalcogen powders, such as sulfur or selenium, may not be suitable for MOCVD processes due to issues with vaporization. To overcome these limitations, a suitable chalcogen source reagent is desired to facilitate the growth of TMDs with large grain sizes, single-crystalline structure, and high quality. The choice of chalcogen precursor impacts the film's morphology, crystal quality, and overall electrical properties. In many cases, the use of a single chalcogen source can lead to undesirable side effects, such as non-uniform film growth, secondary phases, or contamination. These issues can compromise the performance of the TMDs, particularly in sensitive semiconductor applications.

Further, conventional techniques for addressing these issues may be ineffective. For example, gaseous H₂S may be used as a chalcogen-containing precursor in formation of a TMC in lieu of a sulfur source. At some flow rates, a larger grain size of a TMC (e.g., a TMC such as MoS₂) may be obtained. However, despite the grain size, the TMC film quality is often compromised. The degradation in sample quality may be seen by the peak in the photoluminescence spectrum for the TMC. In particular, the FWHM may be large (e.g. 100 meV or more). To improve material quality, it has been determined that an increased sulfur-to-molybdenum (S/Mo) ratio is desired. This ratio may be achieved by an increase in the H₂S flow rate. This adjustment enhances the sample quality, but significantly decreases grain size. It has been determined that this grain size reduction may be attributed to the production of reducing gases (H₂) from the thermal decomposition of H₂S (H₂S→H₂+S), which increases nucleation sites and disrupts uniform growth. The use of other chalcogen precursors may result in other or additional issues. For example, although diethyl sulfide (DES) may be used as a chalcogen precursor, DES may result in carbon residue. Such carbon residue can result in vacancies and other defects in the TMC film. Thus, again, the quality of the film may be compromised. Improved techniques for forming 2D chalcogenides are therefore needed.

A device is described. The device includes a substrate and a transition metal chalcogen (TMC) film formed on the substrate by vapor deposition. The TMC film is continuous over an area of the substrate and at least one monolayer thick. The area has a dimension of at least two inches. In some embodiments, the TMC film is or includes a transition metal dichalcogenide (TMD) film. In some embodiments, the TMC film is characterized by a grain size of at least 5 micrometers. The grain size may be at least ten micrometers, at least twenty micrometers, at least thirty micrometers, at least forty micrometers, or at least fifty micrometers. In some such embodiments, the TMC film is a single crystal.

In some embodiments, the dimension of the area is at least three inches, at least six inches, or at least ten inches. For example, the dimension may be a diameter. In some such embodiments, the area covered by the TMC film is substantially the same as a top surface substrate area of the substrate. Thus, the dimension may be substantially the same as the diameter of an underlying wafer. In some embodiment, the TMC film is characterized by a photoluminescence peak having a full width half max (FWHM) of not more than one hundred meV or not more than seventy-five meV. In some embodiments, the FWHM is not more than sixty meV or not more than fifty meV.

The TMC film may be formed by vapor deposition using a metal precursor, a chalcogen precursor, and at least one additive introduced into a reaction chamber. At least the metal precursor and the chalcogen precursor are separately introduced into the reaction chamber. In some embodiments, the additive(s) are introduced with the chalcogen precursor(s). In other embodiments, the additive(s) are introduced to the reaction chamber separately from the chalcogen precursor(s). In some embodiments, some additive(s) are introduced to the reaction chamber with the chalcogen precursor(s), while other additive(s) are separately introduced to the reaction chamber. The additive(s) are configured to reduce a nucleation density for the TMC film, reduce defects for the TMC film, control the number of nucleation layers, and/or reduce contamination in the TMC film. In some embodiments, the nucleation density for the TMC film is at least 1×10−3 nucleation site per square micrometer and not more than one nucleation site per square micrometer. In some embodiments, the additive(s) include one or more of an oxidizing additive, a reducing and oxidizing (redox) additive, and a residue reducing additive. Multiple of each type of additive (e.g. multiple oxidizing additives) may be used in some embodiments.

A device including a substrate and an electronic structure on the substrate is described. The electronic structure includes a TMD film formed by vapor deposition. As fabricated, the TMD film is continuous over an area of the device and is at least one monolayer thick. The area has a dimension of at least two inches. The TMD film may be a single crystal as fabricated. In some embodiments, the TMD film is formed by vapor deposition using a metal precursor, a chalcogen precursor, and at least one additive introduced into a reaction chamber. At least the metal precursor and the chalcogen precursor are separately introduced into the reaction chamber. The additive(s) are configured to reduce a nucleation density for the TMD film, reduce defects for the TMD film, and/or reduce contamination in the TMD film.

A method is described. The method includes providing a metal precursor, a chalcogen precursor, and at least one additive to a reaction chamber having a substrate. The method also includes forming, in the reaction chamber, a TMC film on a substrate by vapor deposition and using the metal precursor, the chalcogen precursor, and the additive(s). The TMC film is continuous over an area of the substrate and at least one monolayer thick. The area has a dimension of at least two inches. At least the metal precursor and the chalcogen precursor are separately introduced into the reaction chamber. The additive(s) may be configured to at least one of reduce a nucleation density for the TMC film, reduce defects for the TMC film, or reduce contamination in the TMC film. In some embodiments, the additive(s) and the chalcogen precursor are introduced to the reaction chamber together. In some embodiments, the additive(s) and the chalcogen precursor are separately introduced to the reaction chamber. In some embodiments, the TMC film is thicker than a monolayer. In some such embodiments, forming the TMC film further includes forming a first layer of the TMC film. The first layer has a layer top surface. The additive(s) are introduced. A second layer of the TMC film is then formed. In some embodiments, the first and second layers are each one monolayer thick. In some embodiments, the TMC film includes a transition metal dichalcogenide (TMD) film.

Thus, a method and system for producing a TMD film, the resulting TMD film and devices that may incorporate the TMD film are described. The method includes forming the TMD film, for example using MOCVD, using a metal-containing source (e.g., a metal precursor), a chalcogen source (e.g., a chalcogen precursor) and at least one additive. The additive(s) may be used to control the nucleation density, reduce defects, and/or reduce contamination/residue. The additive(s) may be introduced into a reaction chamber with the chalcogen source or may be separately introduced into the reaction chamber. Examples of the additive(s) include but may not be limited to an oxidizing additive (e.g. O₂), a redox (reducing and oxidizing) additive (e.g. SO₂ and/or SCl₂), and/or an additive that reduces or eliminates residues such as carbon (e.g. H₂O vapor). Additives may also be chalcogen-containing additives that may be used to adjust the stoichiometry of the TMC film. Thus, such chalcogen-containing additives may be considered to reduce defects in the TMC film. Combinations of additives may also be used.

Thus, unwanted side effects commonly associated with single chalcogen sources may be mitigated through the method and system described herein. In some embodiments, one or more additives are introduced. The additive(s) and, in some embodiments, the way in which the additives are introduced, may enhance the growth process and improve the material properties of the resulting TMD films. This strategy offers several advantages, including better control over the chalcogen incorporation, improved crystallinity, and the reduction of defect densities. The use of a chalcogen additive represents a promising pathway toward achieving the high-performance TMDs desired for future semiconductor technologies.

Embodiments of systems, methods, additives, films, and devices are described. Various features may be highlighted in certain embodiments. However, particular features may be combined in manners not explicitly described herein. For example, other combinations of additives may be used. Similarly, the deposition method and system are not restricted to cold-wall or hot-wall CVD (Chemical Vapor Deposition) systems. Instead, the method and system described herein may be applied to a variety of other deposition techniques, such as Atomic Layer Deposition (ALD), Physical Vapor Deposition (PVD), Pulsed Laser Deposition (PLD), and/or other techniques. The versatility of the method allows the method to be adapted to various deposition setups, allowing for the controlled growth of high-quality thin films across a range of equipment types and operational conditions. Similarly, the deposition process may be carried out under different pressure conditions, including but not limited to low-pressure chemical vapor deposition (LPCVD), atmospheric pressure chemical vapor deposition (APCVD), and plasma-enhanced chemical vapor deposition (PECVD). The flexibility in pressure conditions allows for the tuning of growth rates, film quality, and uniformity across different substrate sizes, from small wafers to large-area substrates.

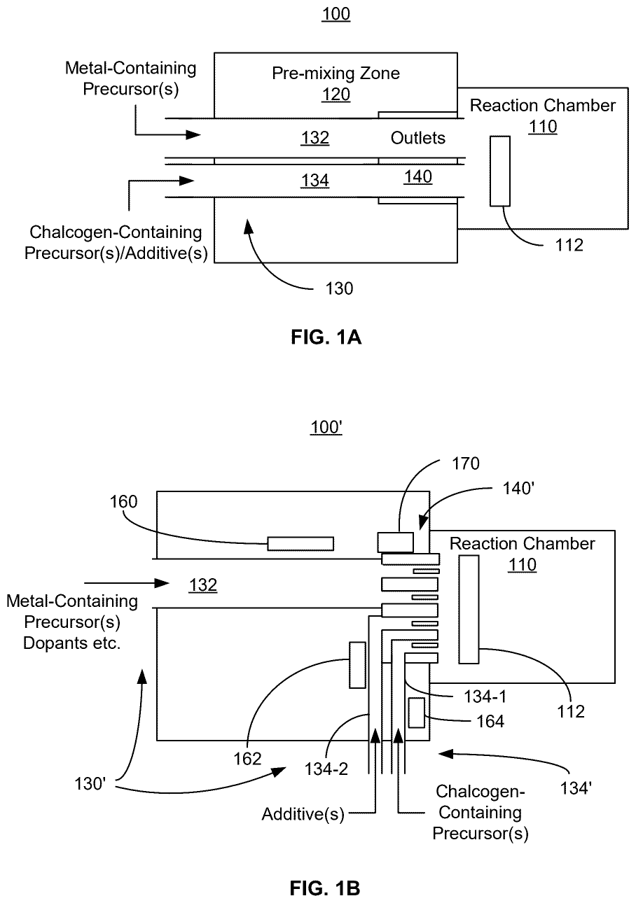

FIGS. 1A-1B depict bock diagrams of embodiments of systems 100 and 100′ for forming transition metal chalcogenide (TMC) films using advanced sources. For example, transition metal dichalcogenide (TMD) films may be formed using advanced sources. Thus, as used herein, TMC films include, but may not be limited to, TMD films. In addition, advanced sources used in formation of such TMD films include but may not be limited to the additives described herein. For clarity, only a portion of systems 100 and 100′ are shown. Systems 100 and 100′ are used to form TMC films in reaction chamber 110 using metal precursor(s), chalcogen precursor(s), and additives. Thus, systems 100 and 100′ may be used to form TMC films using metal-organic chemical vapor deposition (MOCVD).

Referring to FIG. 1A, system 100 includes reaction chamber 110, premixing zone 120, inlets 130, and outlets 140. Reaction chamber 110 includes substrate 112 therein. The TMC film is formed on substrate 112. For example, Si wafers of various sizes (e.g. a 3 inch wafer or a 12 inch wafer) may be used for substrate 112. Suitable materials for substrate 112 may include but may not be limited to silicon (Si), silicon dioxide (SiO₂), silicon nitride (Si₃N₄), glass, sapphire, metals, metal oxides, polymers, and flexible substrates. Deposition on substrate 112 may be performed in system 100 on both rigid and flexible substrates. This may allow for applications in flexible electronics, display technologies, and wearable devices. Inlets 130 include metal precursor(s) inlets 132 and chalcogen-containing precursor/additive(s) inlet 134.

For example, the metal precursor may include W and/or Mo. The precursors may also include dopant(s) and/or other components. The chalcogen precursor(s) may be from sources such as S, Se, and/or Te. Inlets 132 and 134 are isolated routes for the metal precursor(s) (also termed metal source(s)) and chalcogen precursor(s) (also termed chalcogen source(s)). More specifically, the separate, isolated routes 132 and 134 allow both the metal precursor and the chalcogen source to be separately provided to reaction chamber 110. As a result, the metal precursor and chalcogen source only interact downstream, after passing through a dual-gas distribution unit including outlets 140. This controlled separation allows the formation of (TMDs) to occur only after the reactants have merged beyond the dual-gas distribution unit (e.g. in the reaction chamber).

Additionally, the chalcogen additive(s) (termed “additive(s)” herein), which may serve multiple purposes in the reaction are provided. The chalcogen additives can be introduced through the chalcogen inlets 134. In other embodiments the additive may have a separate supply line. This setup offers flexibility in modulating the reaction environment to optimize TMD growth. In some embodiments, the chalcogen precursor flow rate and additive flow rate(s) may be independently controllable even if the additive(s) and chalcogen precursor are provided via the same inlet 134. This may allow for precise tuning of the chalcogen-to-additive ratio in reaction chamber 110. This independent control helps to adjust the TMC film's stoichiometry and crystalline properties, making it suitable for varying electronic, optical, and mechanical properties depending on the application.

Examples of the additive(s) introduced via inlets 134 include but may not be limited to an oxidizing additive (e.g. O₂), a redox (reducing and oxidizing) additive (e.g. SO₂ and/or SCl₂), and/or an additive that reduces or eliminates residues such as carbon (e.g. H₂O vapor). For example, only an oxidizing additive, only a redox additive, only a residue removing additive, a combination of an oxidizing additive and a residue removing additive, a combination of an oxidizing additive and a redox additive, a combination of a redox additive and a residue removing additive, or a combination of an oxidizing additive, a redox additive, and a residue removing additive may be used. In some embodiments, the combination of gases may include (chalcogen source)_{100-y—x}(oxidizing additive)_{y}(redox additive)ₓ. In some embodiments, y is at least 0.3 and not more than 0.8 (e.g., nominally 0.5). One such example is (H₂)_{99.5-x}(O₂)_{0.5}(SCl₂)ₓ. In some embodiments, x is at least 20 and not more than sixty. In some embodiments, x is not more than fifty. Thus, system 100 allows for the formation of TMC films using MOCVD from metal precursor(s), chalcogen precursors and additives.

Referring to FIG. 1B, system 100′ is analogous to system 100. Thus, system 100′ includes reaction chamber 110 having substrate 112 therein, pre-mixing zone 120, inlets 130′, and outlets 140′ that are analogous to reaction chamber 110, substrate 112, pre-mixing zone 120, inlets 130, and outlets 140 of FIG. 1A. Inlets 134 of system 100 have been split into two inlets 134-1 and 134-2 for a chalcogen precursor(s) and additive(s), respectively. Thus, the additives can be introduced to reaction chamber 120 separately from the chalcogen precursor(s). Also shown are temperature control systems 160, 162, 164, and 170. For example, temperature control systems 160 and 170 may provide heating and/or cooling to different portions of pre-mixing zone 120. In the embodiment shown, heating and/or cooling may be provided to outlets 140′ by temperature control system 170 and to inlets 132, 134-1, and 134-2 by temperature control systems 160, 162, and 164.

Using systems 100 and/or 100′, TMC films may be produced from one or more metal precursors, one or more chalcogen precursors, and one or more additives. Such TMC films may include TMD films. The TMC film(s) produced using the additive(s) may have a larger grain size (e.g. having a dimension of at least fifteen micrometers, having the dimension of at least one hundred micrometers, having a dimension of at least one millimeter, having the dimension of at least two inches, and having the dimension of at least twelve inches), may be continuous (e.g. pinhole free) over a larger area (e.g. an area having a dimension such as a diameter of at least two inches, at least three inches, at least four inches, at least six inches, or at least ten inches), may have a higher quality (e.g. fewer defects, a reduced FWHM for the photoluminescence spectrum, and//or the desired crystal structure including being a single crystal in some embodiments), and may have reduced residue (e.g. fewer residue-related defects). Thus, devices incorporating the TMD film may have improved performance.

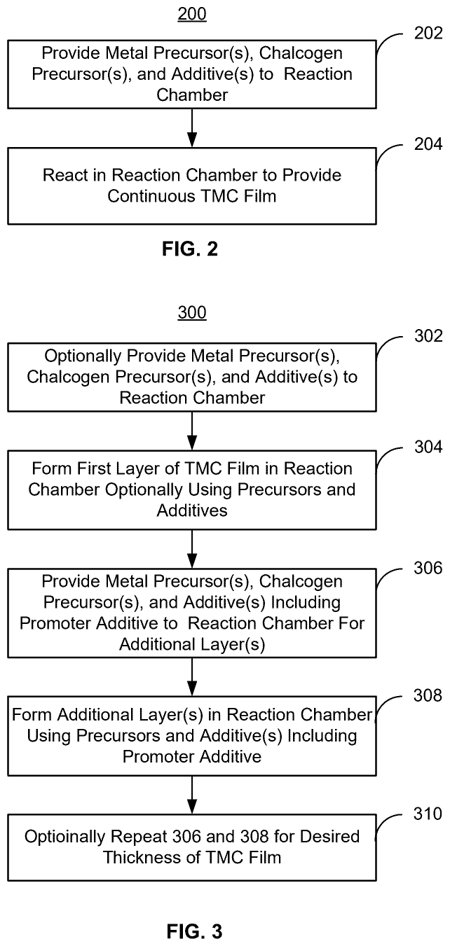

FIG. 2 is a flow chart depicting an embodiment of method 200 for forming TMC (e.g. TMD) films using advanced sources for vapor deposition. Although the processes of method 200 are described in a particular order, another order not inconsistent with the description herein may be utilized. Method 200 is described in the context of vapor deposition system 100. However, another system, including but not limited to system 100′ might be used. In addition, method 200 is described in the context of a single metal precursor and a single chalcogen precursor. Multiple precursors may be used. In addition, other components may be added in addition to the additives described. For example, dopants may be added to the metal precursor.

A metal precursor, a chalcogen precursor, and at least one additive is provided to a reaction chamber having a substrate therein, at 202. At least the metal precursor and the chalcogen precursor are separately introduced into the reaction chamber as part of 202. Thus, mixing of the chalcogen precursor and metal precursor is prevented prior to the precursors entering the reaction chamber. In some embodiments, the additive(s) and the chalcogen precursor are introduced to the reaction chamber together. In some embodiments, the additive(s) and the chalcogen precursor are separately introduced to the reaction chamber. Thus, 202 may or may not include the additive(s) mixing with the chalcogen precursor prior to entering the reaction chamber.

Vapor deposition is performed in the reaction chamber, forming a TMC film on a substrate, at 204. 204 may occur while flow of the precursors and additive(s) continues at 202. In some embodiments, 204 includes controlling the temperature of the reaction chamber and/or the temperatures of the inlets and outlets feeding the reaction chamber to provide the desired conditions for film deposition. In some embodiments, for example, the temperature range in the reaction chamber might be at least 150° C. to high temperatures of 1000° C. or more. Thus, at 204, the TMC film is formed using the metal precursor, the chalcogen precursor, and the additive(s). For example, MOCVD may be used at 204. The TMC film that is formed may be continuous over an area of the substrate and at least one monolayer thick is formed at 204. For example, the reaction carried out at 204 may be carried out for a sufficient time that the TMC film is continuous. In some embodiments, the continuous TMC film is free of pinholes. The TMC film may be thicker than one monolayer. For example, the TMC film may be two or more monolayers thick. Thus, in some embodiments, the TMC film may be considered to be formed monolayer-by-monolayer (or layer-by-layer). In other embodiments, the thickness of the TMC film may vary across the substrate. The area has a dimension (e.g., a diameter or other characteristic length) of at least two inches. The TMC film may be a TMD. The additive(s) used may have a number of functions in 204. The additive(s) may be configured to reduce a nucleation density on the substrate for the TMC film, reduce defects for the TMC film, or reduce contamination in the TMC film.

For example, at 202, a metal precursor (e.g. including Mo) may be provided via inlets 132. In some embodiments, Mo(CO)₆ may be provided to reaction chamber 110 as the metal precursor. In some embodiments, Mo(CO)₆ and H₂O are react to form Mo(CO)₆₋ₓ(OH)ₓ prior to being provided to inlets 132. Thus, Mo(CO)₆₋ₓ(OH)ₓ may be provided to reaction chamber 110 via inlets 132 and outlets 140 as the metal precursor. In addition, a chalcogen precursor such as H₂S and/or DES may be provided via inlets 134. Additives such as O₂, SCl₂, and/or water vapor may also be provided via inlets 134, at 202. At 204, a TMC film is formed via MOCVD or an analogous process. In some embodiments, a TMD, such as MoS₂ is formed.

Additive(s) may be introduced in process 200 to improve quality without adversely affecting grain size (e.g. allowing for both improved quality and larger grain size). In some embodiments, a small amount of oxidizing gas, such as O₂, can be introduced to balance the reaction environment and suppress excess nucleation. For example, a high nucleation density and small grain size are observed with only H₂S as the chalcogen source. In contrast, when an additive such as oxygen (e.g., 1% O₂) is introduced alongside the chalcogen precursor (e.g., H₂S), the system exhibits a substantial decrease in nucleation density and a simultaneous increase in growth rate, resulting in significantly larger grains(e.g., at least 10 micrometers, at least 15 micrometers or more). This suggests that the additive O₂ plays a role in moderating the reducing environment, which reduces nucleation density while accelerating growth, ultimately enabling the formation of larger, high-quality grains. For example, the nucleation density for the TMC film formed using method 200 and an additive such as O₂ may be at least 0.5×10⁻³ or at least 1×10⁻³ nucleation sites per square micrometer and not more than one or not more than ten nucleation sites per square micrometer. In principle, grain sizes that are at least fifteen micrometers, at least one hundred micrometers, at least one millimeter, having the dimension of at least two inches, and having the dimension of at least twelve inches. In some embodiments, a single crystal TMC film may be formed.

Chalcogen source additive(s) that may be provided at 202 and via inlets 134 and/or 134-2 are not restricted to a single agent. For example, sulfur chloride (SCl₂) or thionyl chloride (SOCl₂) can also act as a redox neutralizer (redox additive). Such redox additive(s) may be introduced in addition to or instead of the oxidizing additive(s). For example, the growth of MoS₂ is demonstrated with a fixed concentration of 0.5% O₂. As the concentration of the redox additive increases, a clear trend emerges nucleation density decreases while the grain size correspondingly increases. This relationship suggests that varying the molecular ratio of the redox additive, which can range from 0 to 80%, provides a tunable mechanism for optimizing the balance between nucleation and growth during the deposition process.

Other additive(s) might also be used. One chalcogen precursor for the growth of TMDs in MOCVD is diethyl sulfide (DES). Under high temperatures, DES readily forms unwanted carbon residue in TMDs due to the organic functional group. Therefore, additive(s) such as H₂O (e.g., water vapor) may serve as a carbon remover in the system. H₂O helps eliminate residual carbon, resulting in a clean MoS₂ layer. Consequently, the MOS₂ TMC (TMD, in this case) film formed may have fewer defects due to the carbon. Other additive(s) may be used to address other and/or additional residue. Thus, in addition to or in lieu of oxidizing additives and/or redox additives, residue reducing/removing additives may be introduced. Other additive(s) may also be introduced for other purposes. This example highlights the versatility of additives, demonstrating that they can serve as functional group removers in addition to their role in redox reactions.

The additive(s) may also function as remover(s) of unwanted functional groups, broadening its applicability in the MOCVD process. By carefully selecting the appropriate additive(s), both the chemical environment and the quality of the resulting TMD films can be precisely controlled, leading to optimized material properties. This flexibility in the use of additives may be crucial for overcoming the inherent trade-offs between grain size, quality, and nucleation, ultimately enabling the scalable production of high-performance TMDs for advanced electronic applications.

In some embodiments, the primary chalcogen source (e.g., the chalcogen precursor) may include but is not limited to S, Se, Te, H₂S, SCl₂, dimethyl sulfide (DMS), diethyl sulfide (DES), H₂Se, H₂Te, and diethyl selenide (DESe), among others. Any compound containing a chalcogen element (S, Se, Te, etc.) may be considered as a potential main chalcogen source, or chalcogen precursor, for method 200. This encompasses a wide variety of chalcogen-based compounds, whether gaseous, liquid, or solid at room temperature, that can be introduced in a vapor phase or through other transport mechanisms. The use of such versatile sources allows flexibility in achieving the desired material characteristics in the deposition process.

The additive(s), which may serve as redox neutralizers, moderators of the chemical vapor deposition process, or may otherwise be used for improving the TMC film and/or deposition process may include, but are not limited to: NO, NO₂, N₂O, N₂O₃O₂, O₃, H₂O₂, B₂H₆, PH₃, PCl₃, PBr₃, NH₃, F₂, Cl₂, Br₂, I₂, HCl, HBr, HI, SCl₂, S₂Cl₂, S₂Br2, S₂F10, SO₃, SO₂, CS₂, SOCl₂, CO, HNO₂, HClO, HClO₂, HClO₃, HClO₄, SeO₂, SeOCl₂, SeOF₂, SF₄, SF₆, H₂O etc. These compounds may actively participate in redox balancing, acting as oxidizing or reducing agents, thereby stabilizing the reaction environment, preventing unwanted side reactions, removal of residues, or influencing the growth kinetics and film morphology.

The additive(s) used in conjunction with the main chalcogen source may also contain chalcogen elements, further contributing to the deposition process. Examples of such chalcogen-containing additives may include but are not limited to CS₂, SO₂, CSe₂, CH₃SH, and S₂OF₂, among others. These additive(s) not only introduce additional chalcogen elements but can also modulate the overall stoichiometry of the deposited film, helping to achieve the desired phase, grain size, and purity. Thus, such chalcogen-containing additives may be considered to be configured to reduce the defects in the TMC film being formed.

The additives provided at 202 and used in forming the TMC film at 204 are not limited to a single chemical species; multiple additives can be introduced simultaneously to create a synergistic effect. This combination of chemicals may be used to finely tune the deposition environment, providing optimized growth conditions. For example, H₂S, SO₃, and O₂ may be used in combination, where H₂S acts as the primary chalcogen source, and SO₃ and O₂ serve as additives that influence oxidation states, chemical balance, and deposition kinetics. Such multi-additive strategies can enhance the control over film composition, morphology, and other material properties.

The additive(s) need not participate in redox or other particular reactions within the system. For example, the additive(s) may function solely as a scavenger or remover of undesired functional groups from the deposition environment or the growing film. For instance, H₂O can act as a functional group remover (e.g., a residue remover) for diethyl sulfide (DES), ensuring that the film's final composition is not compromised by unwanted side products. Additive(s) that may act as functional group removers (e.g., residue removers) may include but are not limited to, H₂O, H₂, CO, F₂, Cl₂, Br₂, I₂, HCl, HBr, HI, S₂Cl₂, SCl₂, NO, NO₂, N₂O, and NH₃. These compounds target and may eliminate specific reactive groups, thereby refining the deposition process, removing residues, and improving film quality.

Although described primarily in the context of a chalcogen precursor, multiple chalcogen precursors may be used to provide TMD(s). Thus, a single source/precursor, multiple sources/precursors, a single additive, and/or multiple additives may be combined in various manners (e.g. a single chalcogen precursor with a single additive, a single chalcogen precursor with multiple additives, multiple chalcogen precursors with a single additive, multiple chalcogen precursors with multiple additives). Consequently, alloyed TMCs/TMDs (e.g., MoS₂₋ₓTeₓ) may be produced with the desired combination of chalcogen source(s) and additive(s).

The deposition temperature for process 200 may not be limited to a single range and can be adjusted based on the substrate material, desired film composition, and specific chalcogen or additive sources. In some embodiments, the temperature range can span from 150° C. to high temperatures exceeding 1000° C., making the process applicable for various temperature-sensitive substrates or high-temperature applications.

The substrate materials used in the process are not limited to any specific type. Suitable substrates include but are not limited to silicon (Si), silicon dioxide (SiO₂), silicon nitride (Si₃N₄), glass, sapphire, metals, metal oxides, polymers, and flexible substrates. Method 200 allows for deposition on both rigid and flexible substrates, enabling applications in flexible electronics, display technologies, and wearable devices.

Method 200 may include a pre-treatment step where the substrate is cleaned or activated by methods such as plasma treatment, chemical etching, or thermal annealing. This ensures that the substrate surface is prepared for optimal film adhesion, enhancing film uniformity and reducing defects in the deposited layer.

The chalcogen source flow rate and additive flow rates may be independently controllable in 202, allowing for precise tuning of the chalcogen-to-additive ratio in the reaction chamber. This independent control helps to adjust the film's stoichiometry and crystalline properties, making it suitable for varying electronic, optical, and mechanical properties depending on the application.

Method 200 also allows for post-deposition annealing of the TMC film, which can be performed in an inert or reactive atmosphere (e.g., N₂, Ar, H₂, or O₂) to further improve film crystallinity, grain size, and electronic properties. The annealing aids in the TMD film attaining the desired phase, purity, and performance characteristics after deposition.

Method 200 may be further enhanced by the introduction of dopants into the film during or after deposition. For example, 202 may include providing dopants via inlets 130. Suitable dopant sources may include but are not limited to phosphine (PH₃), diborane (B₂H₆), arsine (AsH₃), and germane (GeH₄). The incorporation of dopants allows for precise control over the electrical properties of the film, making it suitable for applications in logit, memory, and electro-optical devices.

The techniques allow for selective-area deposition by utilizing masks or patterned substrates to confine film growth to designated regions. This approach facilitates the fabrication of micro-and nano-scale electronic devices, eliminating the need for complex post-deposition photolithography steps.

Method 200 and systems 100 and 100′ may further allow for the selective modification, enhancement, or repair of the TMD layer during or post-device fabrication, including after transfer, etching or channel definition. This may be achieved by introducing targeted chalcogen sources or additives to replenish or heal defect sites, restore stoichiometric balance, and/or improve electronic properties.

The deposition process at 202 and 204 may be performed under continuous or pulsed flow conditions, allowing control over layer thickness, interface sharpness, and film composition. Pulsed flow techniques, such as in atomic layer deposition (ALD), allow for precise control of monolayer deposition, ensuring ultra-thin and conformal coatings.

Method 200 and systems 100 and 100′ may incorporate plasma or UV-enhanced process(es) to activate the chemical precursors or improve the reactivity of the chalcogen sources and additives. Plasma-enhanced deposition can help reduce the process temperature or enhance film quality, making it suitable for sensitive substrate materials.

The chalcogen sources (for the chalcogen precursors) and/or additives may be delivered in different states, including vapor phase, liquid phase, or solid precursors that are vaporized or sublimated in situ. This flexibility provides compatibility with a wide range of precursor delivery systems, allowing for easy integration into existing equipment.

Systems 100 and/or 100′ may allow for in-situ monitoring of the deposition process through techniques such as optical emission spectroscopy (OES), mass spectrometry, or ellipsometry. These monitoring techniques provide real-time feedback on the deposition environment and film growth, enabling closed-loop control of the process for enhanced precision and reproducibility.

The method and system may produce thin films with varying morphologies, including amorphous, polycrystalline, and single-crystalline structures. The choice of deposition conditions, precursor materials, and additives allows for precise control over the film's microstructure, making it suitable for a broad range of applications, from electronic devices to catalysis.

FIG. 3 is a flow chart depicting an embodiment of method 300 for forming TMC (e.g. TMD) films using advanced sources for vapor deposition. Although the processes of method 300 are described in a particular order, another order not inconsistent with the description herein may be utilized. Method 300 is described in the context of vapor deposition systems 100 and 100′. However, another system might be used. In addition, method 300 is described in the context of a single metal precursor and a single chalcogen precursor. Multiple precursors may be used. In addition, other components may be added in addition to the additives described. For example, dopants may be added to the metal precursor.

A metal precursor, a chalcogen precursor, and at least one additive are optionally provided to a reaction chamber having a substrate therein, at 302. In some embodiments, 302 is analogous to 202 of method 200. At 304, a first layer of a TMC film is provided by using vapor deposition. In some embodiments, 304 is analogous to 204 of method 200. Thus, the first layer of the TMC film formed may have the desired properties. Stated differently, the first layer of the TMC film may be formed in an analogous way to the films described above. Thus, the first layer may have analogous properties to those described herein. In other embodiments, the first layer of the TMC film may be formed at 304 and/or 302 in another manner.

A metal precursor, a chalcogen precursor, and at least one additive are optionally provided to a reaction chamber having a substrate therein, at 306. In some embodiments, 306 is analogous to 202 of method 200. In addition, particular additive(s) may be used as part of 306. In some such embodiments, the particular additive(s) are provided to the reaction chamber first. In some such embodiments, the particular additive(s) are provided to the reaction chamber along with remaining additive(s) (if any), the chalcogen precursor(s), and the metal precursor(s). Such additives may promote growth of subsequent layer(s). Consequently, such an additive is termed a promoter additive. For example, an additive such as sulfur chloride (SCl₂) might be used as the promoter additive. Sulfur chloride may function as a promoter that enables layer-by-layer growth of TMD films. At 308, another layer of the TMC film is grown using vapor deposition in the presence of the metal precursor(s), the chalcogen precursor(s), and the additive(s) that include the promoter additive.

After forming a first-layer the TMD film at 302 and 304, the introduction of the promotor additive at 306 and use in 308 promotes the controlled initiation of the second-layer formation on the pre-existing surface. In the absence of the promoter additive, the subsequent deposition may result in discontinuous or island-type growth. When the promoter additive is present, the process transitions to a layer-by-layer regime, yielding a continuous and uniform second layer. Atomic force microscopy (AFM) may be used confirm whether atomically flat terraces exist across the film, indicating uniform 2L coverage. At 310, processes 306 and 308 may be repeated to grow a thicker TMD film including multiple layers.

For example, at 302, a metal precursor (e.g. including Mo) may be provided via inlets 132. In some embodiments, Mo(Co)₆ may be provided to reaction chamber 110 as the metal precursor. In some embodiments, Mo(Co)₆ and H₂O are react to form Mo(CO)₆₋ₓ(OH)ₓ prior to being provided to inlets 132. Thus, Mo(CO)₆₋ₓ(OH)ₓ may be provided to reaction chamber 110 via inlets 132 and outlets 140 as the metal precursor. In addition, a chalcogen precursor such as H₂S and/or DES may be provided via inlets 134 or 134-1. Additives such as O₂, SCl₂, and/or water vapor may also be provided via inlets 134 or 134-2, at 302. At 304, a TMC layer is formed in reaction chamber 110 via MOCVD or an analogous process. In some embodiments, a TMD, such as MoS₂ is formed. However, in other embodiments, the first layer of the TMC film is formed in another manner.

At 306, the metal precursor, chalcogen precursor, and additives are provided to reaction chamber 110 via inlets 130 or 130′ and outlets 140 or 140′. These precursors and additives may be the same as or different from additive(s) used for 302. However, the promoter additive, such as SCl₂ is provided as an additive part of 306. In some embodiments, this promoter additive is provided first, to promote formation of the second layer of the TMC film.

The promoter additive may be provided at 306 even if the additive was not used as part of 302 and 304. At 308, the second layer of the TMC film is grown. For example, another layer (e.g. another monolayer) of the TMD film, such as MoS₂, is formed. In some embodiments, Thus, a TMC (e.g., a TMD film) that is thicker than a monolayer may be provided. The TMD film so provided may share the benefits discussed in the context of systems 100 and 100′ and method 200. For example, the TMC film provided using method 300 may be continuous over larger areas, have a larger grain size or be single crystal, be thicker, have the desired stoichiometry and be of higher quality. In addition, the TMC film may be grown layer-by-layer and have a corresponding topology. Thus, performance of electronic devices using such a TMC film may be improved.

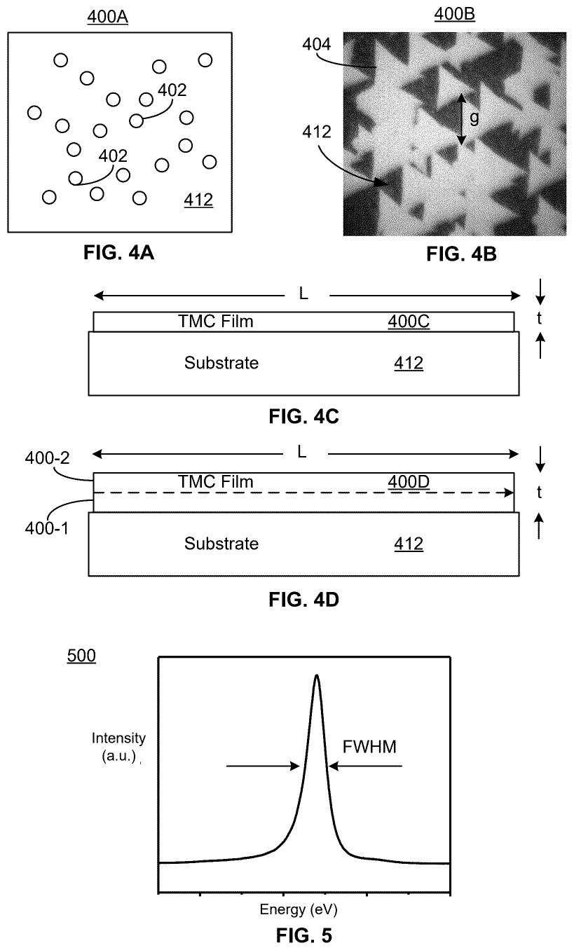

FIGS. 4A-4D depict embodiments of TMC (e.g. TMD) film(s) 400A, 400B, 400C, and 400D formed using advanced sources for vapor deposition. For clarity, only a portion of TMC films 400A, 400B, 400C, and 400D are shown. Further, FIGS. 4A-4D are not to scale. TMC films 400A, 400B, 400C, and 400D may be formed using method(s) 200 and/or 300 and system(s) 100 and/or 100′. In some embodiments, other method(s) and/or other system(s) may be used. However, additives analogous to the additives described herein are used in formation of TMC films 400A, 400B, 400C, and 400D.

FIG. 4A depicts TMC film 400A during formation. Also shown is underlying substrate 412 that is analogous to substrate 112. Thus, TMC film 400A may be present shortly after 204 or 304 of method 200 or 300, respectively, starts. Thus, nucleation sites 402 (of which only two are labeled) are shown. Nucleation sites 402 indicate locations at which a TMC film is starting to grow on substrate 412. In some embodiments, the additive(s) used affect the density of nucleation sites 402. In some embodiments, the density of nucleation sites 402 is at least 0.5×10⁻³ nucleation sites per square micrometer (0.5×10⁻³ sites/μm²) and not more than ten nucleation sites per square micrometers (10 sites/μm²). In some embodiments, the density of nucleation sites 402 is at least 1×10⁻³ nucleation sites per square micrometer (1×10⁻³ sites/μm²) and not more than nucleation site per square micrometers (1 site/μm²). Other densities of nucleation sites are possible. However, the density of sites provided is desired to be sufficient for the TMC film being formed to have the desired grain size, thickness, film quality, and/or other characteristics.

FIG. 4B depicts TMC film 400B during formation. Also shown is underlying substrate 412 that is analogous to substrate 112. Thus, TMC film 400B may be present during 204 or 304 of method 200 or 300, respectively. Thus, grains 404 (of which only one is labeled) have formed. Grains 404 have a characteristic size, g. In some embodiments, TMC film 400B is characterized by a grain size of at least 5 micrometers (g≥5 μm). The grain size may be at least ten micrometers (g≥10 μm), at least twenty micrometers (g≥20 μm), at least thirty micrometers (g≥30 μm), at least forty micrometers (g≥40 μm), or at least fifty micrometers (g≥50 μm). Other grain sizes are possible. In addition, the uniformity in the size of grains 404 may be improved. In some such embodiments, the TMC film 400B being formed is a single crystal. In other embodiments, the TMC film 400B being formed is polycrystalline. However, the TMC film being formed may have the desired grain size, thickness, film quality, and/or other characteristics at least in part due to the use of additives described herein.

FIG. 4C depicts TMC film 400C, which may be a TMD film. in some embodiments, TMC film 400C is completed. In other embodiments, formation of a thicker film may continue. Also shown is underlying substrate 412 that is analogous to substrate 112. TMC film 400C may have the desired grain size, grain uniformity, and film quality. In addition, TMC film 400C is continuous over a region having a characteristic length L. Thus, TMC film 300 does not include islands separated by apertures (e.g., apertures that are at least one-tenth of the grain size, at least one half of the grain size, at least 0.5 micrometer in diameter, or at least one micrometer in diameter). In some such embodiments, TMC film 300 does not include pinholes. In some embodiments, the dimension, L, corresponding to the area of the region is at least two inches. In some embodiments, L is at least three inches, at least six inches, or at least ten inches. In some embodiments, L is approximately (or greater than) twelve inches. For example, the dimension, L, may be at or near the diameter of the underlying substrate 412. Thus, the area covered by TMC film 400C may be substantially the same as a top surface substrate area of substrate 412. Further, the thickness, t, of TMC film 400C may be at least a monolayer. In some embodiments, TMC film 400 is a monolayer thick. Thus, a TMC film may be formed that has the desired grain size, thickness, film quality, and/or other characteristics at least in part due to the use of additives described herein.

Although substrate and TMC film 400C are shown as being substantially flat, in some embodiments, there may be another topology. For example, substrate 412 may have structures formed thereon. In such embodiments, TMC film 400C may conform to the underlying topology. For example, pillars, fins, or other structures used in forming three-dimensional electronic devices may be provided on substrate 412. TMC film 400C may conform to this topology, allowing formation for devices such as FinFETS. Other structures and/or other electronic devices may be formed in other embodiments. Further, although shown as residing directly on substrate 412, other intervening layers and/or structures may be present between substate 412 and TMC film 400C.

FIG. 4D depicts TMC film 400D, which may be a TMD film. in some embodiments, TMC film 400D is completed. In other embodiments, formation of a thicker film may continue. Also shown is underlying substrate 412 that is analogous to substrate 112. TMC film 400D may have the desired grain size and film quality. In addition, TMC film 400D is continuous over a region having a characteristic length L. In addition, TMC film 400D is thicker than TMC film 400C. Thus, TMC film 400D may be formed using method 300. More specifically, a second layer 400-2 has been formed on first layer 400-1. In some embodiments, first layer 400-1 is analogous to TMC film 400C. Both first layer 400-1 and second layer 400-2 are continuous over the same area (e.g., have the same characteristic length L) as TMC 400C. In addition, in some embodiments, TMC film 400D is single crystal. In some embodiments, TMC film 400D is polycrystalline with the grain sizes and uniformities described herein. In some embodiments, TMC film 400D is amorphous. The thickness, t, of TMC film 400D may be greater than monolayer. In some embodiments, TMC film 400 is two monolayers thick. Thus, a TMC film may be formed that has the desired grain size, thickness, film quality, and/or other characteristics at least in part due to the use of additives described herein.

Although substrate and TMC film 400D are shown as being substantially flat, in some embodiments, there may be another topology. For example, substrate 412 may have structures formed thereon. In such embodiments, TMC film 400D may conform to the underlying topology in a manner analogous to TMC film 400C. Thus, electronic devices such as FinFETS, other structures and/or other electronic devices may be formed using TMC film 400D in other embodiments. Further, although shown as residing directly on substrate 412, other intervening layers and/or structures may be present between substate 412 and TMC film 400D.

Thus, TMC films such as TMC film 400C and/or 400D having the desired film quality, grain size, reduced residue, stoichiometry and/or other characteristics may be formed. For example, the film quality of TMC films described herein may be indicated by photoluminescence. FIG. 5 depicts an embodiment of a graph 500 of the photoluminescence for a TMC film (e.g. a TMC film) formed using advanced sources. For example, graph 500 may be the photoluminescence of TMC films 400C and/or 400D. However, graph 500 is for explanatory purposes only and not intended to depict properties of a specific TMC film. The quality of the TMC film is indicated by the full width half max (FWHM) of the corresponding peak in the photoluminescence. In some embodiments, the FWHM for TMC films formed in accordance with the methods and systems described herein is not more than one hundred meV. In some embodiments, the FWHM is not more than seventy-five meV. The FWHM may be not more than sixty meV. In some embodiments, the FWHM is not more than fifty meV.

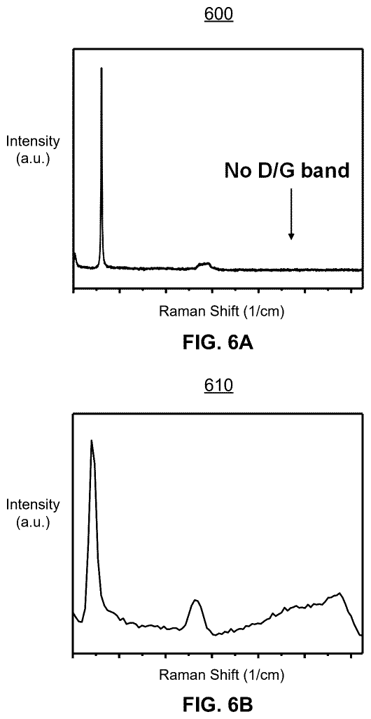

In another example, TMC films formed in accordance with the methods and systems described herein may have reduced residue. For example, use of water vapor as an additive may reduce the carbon residue for TMC films formed using DES as a chalcogen precursor. FIGS. 6A-6B depict embodiments of Raman spectra 600 and 610 for TMC films (e.g. TMD films) formed with and without using advanced sources for vapor deposition. For example, graph 600 may be the Raman spectrum of TMC film 400C and/or 400D formed using DES and including water vapor as an additive. Graph 610 may be the Raman spectrum for a TMC film formed using DES without the use of advanced sources (e.g., additives). However, graphs 600 and 610 for explanatory purposes only and not intended to depict properties of specific TMC films. Graph 600 does not include D and G bands, while graph 600 includes D and G bands corresponding to carbon. Because carbon residue was accounted for using water vapor, the corresponding defects in the TMD film for graph 600 are not present. Thus, the TMC film formed in accordance with the methods and system described herein may have fewer defects. Consequently, using the systems and methods described herein, including incorporating advanced sources such as the additives described, may provide TMD films having improved characteristics. For example, better control over chalcogen incorporation, improved crystallinity, and reduction of defects in TMD/TMC films may be provided using scalable techniques.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A device, comprising:
a substrate; and
a transition metal chalcogen (TMC) film formed on the substrate by vapor deposition, the TMC film being continuous over an area of the substrate and being at least one monolayer thick, the area having a dimension of at least two inches.

2. The device of claim 1, wherein the TMC film includes a transition metal dichalcogenide (TMD) film.

3. The device of claim 1, wherein the TMC film is a single crystal.

4. The device of claim 1, wherein the TMC film is characterized by a grain size of at least 5 micrometers.

5. The device of claim 4, wherein the grain size is at least ten micrometers.

6. The device of claim 1, wherein the dimension of the area is at least three inches.

7. The device of claim 6, wherein the area is substantially the same as a top surface substrate area of the substrate.

8. The device of claim 1, wherein the TMC film is characterized by a photoluminescence peak having a full width half max (FWHM) of not more than seventy-five meV.

9. The device of claim 8, wherein the FWHM is not more than sixty meV.

10. The device of claim 1, wherein the TMC film is formed by vapor deposition using a metal precursor, a chalcogen precursor, and at least one additive introduced into a reaction chamber, at least the metal precursor and the chalcogen precursor being separately introduced into the reaction chamber, the at least one additive being configured to at least one of reduce a nucleation density for the TMC film, reduce defects for the TMC film, or reduce contamination in the TMC film.

11. The device of claim 10, wherein the at least one additive includes at least one of an oxidizing additive, a reducing and oxidizing (redox) additive, and a residue reducing additive.

12. A device, comprising:
a substrate; and
an electronic structure on the substrate, the electronic structure including a transition metal dichalcogenide (TMD) film formed by vapor deposition, as fabricated the TMD film being continuous over an area of the device and being at least one monolayer thick, the area having a dimension of at least two inches, the TMD film being a single crystal as fabricated.

13. The device of claim 12, wherein the TMD film is formed by vapor deposition using a metal precursor, a chalcogen precursor, and at least one additive introduced into a reaction chamber, at least the metal precursor and the chalcogen precursor being separately introduced into the reaction chamber, the at least one additive being configured to at least one of reduce a nucleation density for the TMD film, reduce defects for the TMD film, or reduce contamination in the TMD film.

14. A method, comprising:
providing a metal precursor, a chalcogen precursor, and at least one additive to a reaction chamber having a substrate; and
forming, in the reaction chamber, a transition metal chalcogen (TMC) film on a substrate by vapor deposition and using the metal precursor, the chalcogen precursor, and the at least one additive, the TMC film being continuous over an area of the substrate and being at least one monolayer thick, the area having a dimension of at least two inches;
wherein at least the metal precursor and the chalcogen precursor are separately introduced into the reaction chamber.

15. The method of claim 14, wherein the at least one additive is configured to at least one of reduce a nucleation density for the TMC film, reduce defects for the TMC film, or reduce contamination in the TMC film.

16. The method of claim 14, wherein the at least one additive and the chalcogen precursor are introduced to the reaction chamber together.

17. The method of claim 14, wherein the at least one additive and the chalcogen precursor are separately introduced to the reaction chamber.

18. The method of claim 14, wherein the TMC film is greater than one monolayer thick and wherein the forming further includes:
forming a first sublayer of the TMC film, the first sublayer having a sublayer top surface;
introducing the at least one additive; and
forming a second sublayer of the TMC film.

19. The method of claim 18, wherein the first sublayer and the second sublayer are each one monolayer thick.

20. The method of claim 17, wherein the TMC film includes a transition metal dichalcogenide (TMD) film.
